(19) United States
(12) Patent Application Publication
(10) Pub. No.: US 2012/0326795 A1
(43) Pub. Date: Dec. 27, 2012

(54) VCO CALIBRATION SCHEME

(75) Inventors: Janice Chiu, Tustin, CA (US); Srinivas Badam, Irvine, CA (US)

(73) Assignee: BROADCOM CORPORATION, IRVINE, CA (US)

(21) Appl. No.: 13/170,106

(22) Filed: Jun. 27, 2011

(51) Int. Cl. H03L 7/00; H03L 7/08

(52) U.S. Cl. 331/17; 327/157

(57) ABSTRACT

A technique to use a two-step calibration procedure to calibrate a voltage controlled oscillator (VCO) of a phase-locked loop. The first calibration step is an open-loop calibration procedure in which a control voltage of the VCO is temperature compensated and the VCO is tuned using a search routine to generate a corresponding output frequency based on the control voltage. The second step is a closed-loop calibration procedure to adjust the tuning components of the VCO to correct for a 1 LSB error.

### BACKGROUND OF THE INVENTION

1. Technical Field of the Invention

The embodiments of the invention relate to VCOs and, more particularly, to a temperature compensated calibration procedure in the operation of VCOs.

2. Description of Related Art

Various wireless communication systems are known today to provide links between devices, whether directly or through a network. Such communication systems range from national and/or international cellular telephone systems, the Internet, point-to-point in-home system, as well as other systems. Communication systems typically operate in accordance with one or more communication standards or protocol. For instance, wireless communication systems may operate using protocols, such as IEEE 802.11, Bluetooth™, advanced mobile phone services (AMPS), digital AMPS, global system for mobile communications (GSM), code division multiple access (CDMA), local multi-point distribution systems (LMDS), multi-channel-multi-point distribution systems (MMDS), as well as others.

For each wireless communication device to participate in wireless communications, it generally includes a built-in radio transceiver (i.e., receiver and transmitter) or is coupled to an associated radio transceiver (e.g., a station for in-home and/or in-building wireless communication networks, modem, etc.). Typically, the transceiver includes a baseband processing stage and a radio frequency (RF) stage. The baseband processing provides the conversion from data to baseband signals for transmitting and baseband signals to data for receiving, in accordance with a particular wireless communication protocol. The baseband processing stage is coupled to a RF stage (transmitter section and receiver section) that provides the conversion between the baseband signals and RF signals. The RF stage may be a direct conversion transceiver that converts directly between baseband and RF or may include one or more intermediate frequency stage(s).

Furthermore, wireless devices typically operate within certain radio frequency ranges or band established by one or more communications standards or protocols. A local oscillator generally provides a local oscillation signal that is used to mix with received RF signals or baseband signals that are to be converted to RF signals in the modulation/demodulation stage of the RF front end. A synthesizer may be used to set the frequencies to drive the local oscillator to provide the desired frequencies for mixing, in which the desired frequencies are generally based on the channel frequencies established for the particular standard or protocol.

To generate various reference signals, clock signals, channel frequencies, etc., a wireless device typically uses a phase locked loop (PLL) circuit to produce a signal that locks to a particular frequency. Furthermore, in a typical (PLL), a control voltage is input to a voltage controlled oscillator (VCO), in which the control voltage establishes the frequency output from the VCO. Accordingly, for stable performance, the VCO should generate and maintain a locked frequency for a selected control voltage input.

In a wireless communication device, such as a 3G or 4G (3^{rd} generation or 4^{th} generation) cellular telephone, the synthesizer alters its output depending on the channel or carrier frequency selected. In some instances, just the control voltage to the VCO is changed for the new frequency, while in other systems, other component selections are made along with a change in the control voltage. Furthermore, the operational characteristics of the VCO and the PLL comprising the synthesizer may vary if appreciable temperature variations are encountered by the device. Therefore, a calibration scheme is desirable to ensure that the VCO and the closed loop PLL operate within desired tolerances. Such calibration scheme may be utilized when the channel or carrier frequency is changed for device operation.

Accordingly, there is a need for a calibration scheme to ensure that the VCO and the closed loop PLL operate within desired tolerances and in which the calibration scheme may be utilized when the channel or carrier frequency is changed for device operation.

### BRIEF DESCRIPTION OF THE DRAWINGS

FIG. 1 is a block diagram showing a wireless communication system in accordance with one embodiment for practicing the present invention.

FIG. 2 is a schematic block diagram showing an embodiment of a wireless communication device for practicing the present invention.

FIG. 3 is a block diagram of a PLL, in which the present invention is implemented to calibrate a VCO circuit of the PLL.

FIG. 4 is a circuit schematic diagram that illustrates one embodiment of a circuit for implementing a VCO.

FIG. 5 is a graph illustrating one example of VCO output frequency vs. VCO control voltage over temperature.

FIG. 6 is a circuit block diagram showing components of a PLL of FIG. 3 that are utilized for open-loop calibration.

FIG. 7 is a circuit block diagram showing components of a PLL of FIG. 3 that are utilized for closed-loop calibration.

FIGS. 8A-8B show a flow diagram of a procedure for performing the open-loop calibration and closed-loop calibration in practicing one embodiment of the invention.

FIG. 9 is a graph showing one example result obtained for the VCO after performing the open-loop calibration procedure.

FIG. 10 is a graph showing one example result obtained for the VCO after performing the open-loop calibration and the closed-loop calibration procedures.

### DETAILED DESCRIPTION OF THE INVENTION

The embodiments of the present invention may be practiced in a variety of devices that utilize a voltage controlled oscillator (VCO) and, in particular, a VCO used within a phase locked loop (PLL). However, the invention need not be limited to a PLL. Furthermore, the examples described herein describe the use of the VCO within a device having wireless communication capability, such as 3G and 4G mobile (or cellular) devices. However, the invention need not be limited to such wireless devices. The invention may be practiced with both wired and wireless devices.

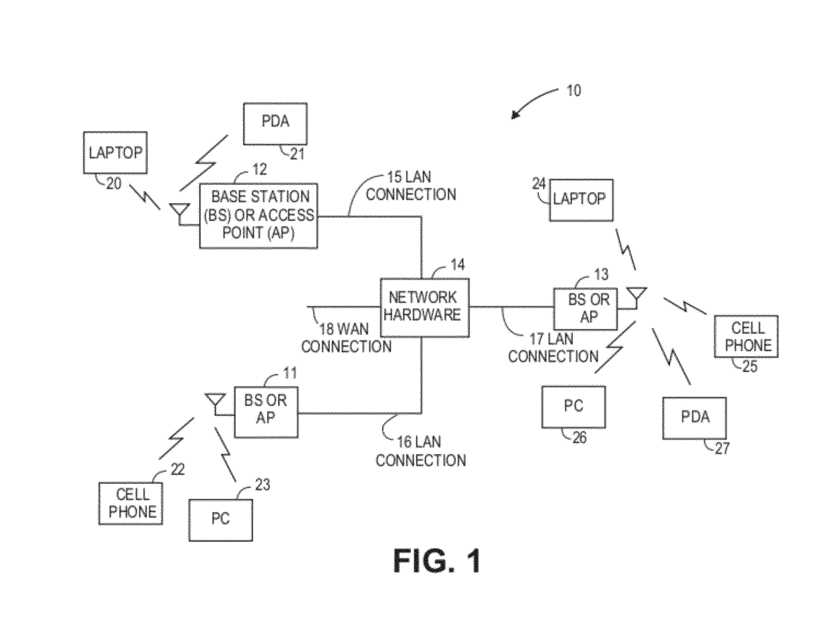

FIG. 1 illustrates one environment for practicing the present invention. FIG. 1 shows a communication system 10 that includes a plurality of base stations (BS) and/or access points (AP) 11-13, a plurality of wireless communication devices 20-27 and a network hardware component 14. The wireless communication devices 20-27 may be laptop computers 20 and 24, personal digital assistants 21 and 27, personal computers 23 and 26, cellular telephones 22 and 25, and/or any other type of device that supports wireless communications.

The base stations or access points 11-13 may be operably coupled to network hardware 14 via respective local area network (LAN) connections 15-17. Network hardware 14, which may be a router, switch, bridge, modem, system controller, etc., may provide a wide area network (WAN) connection 18 for communication system 10. Individual base station or access point 11-13 generally has an associated antenna or antenna array to communicate with the wireless communication devices in its area. Typically, the wireless communication devices register with a particular base station or access point 11-13 to receive services within communication system 10. For direct connections (i.e., point-to-point communications), wireless communication devices may communicate directly via an allocated channel.

Typically, base stations are used for cellular telephone systems (including 3G and 4G systems) and like-type systems, while access points are used for in-home or in-building wireless networks. Regardless of the particular type of communication system, each wireless communication device includes a built-in radio and/or is coupled to a radio. The radio includes a linear amplifier and/or programmable multi-stage amplifier to enhance performance, reduce costs, reduce size, and/or enhance broadband applications. The radio also includes, or is coupled to, an antenna or antennas having a particular antenna coverage pattern for propagating of outbound RF signals and/or reception of inbound RF signals.

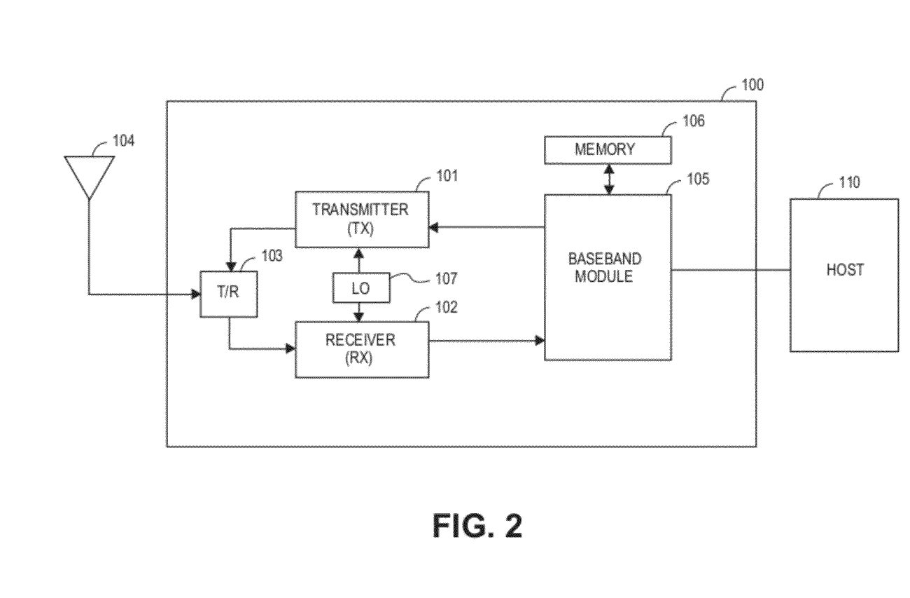

FIG. 2 is a schematic block diagram illustrating part of a wireless communication device 100 that includes a transmitter (TX) 101, receiver (RX) 102, local oscillator (LO) 107 and baseband module 105. Baseband module 105 provides baseband processing operations. In some embodiments, baseband module 105 is or includes a digital-signal-processor (DSP). Baseband module 105 is typically coupled to a host unit, applications processor or other unit(s) that provides operational processing for the device and/or interface with a user.

In FIG. 2, a host unit 110 is shown. For example, in a notebook or laptop computer, host 110 may represent the computing portion of the computer, while device 100 is utilized to provide WiFi and/or Bluetooth components for communicating wirelessly between the computer and an access point and/or between the computer and a Bluetooth device. Similarly, for a handheld audio or video device, host 110 may represent the application portion of the handheld device, while device 100 is utilized to provide WiFi and/or Bluetooth components for communicating wirelessly between the handheld device and an access point and/or between the handheld device and a Bluetooth device. Alternatively, for a mobile telephone, such as a cellular phone, device 100 may represents the radio frequency (RF) and baseband portions of the phone and host 110 may provide the user application/interface portion of the phone. Furthermore, device 100 may be incorporated in one or more of the wireless communication devices 20-27 shown in FIG. 1.

A memory 106 is shown coupled to baseband module 105, which memory 106 may be utilized to store data, as well as program instructions that operate on baseband module 105. Various types of memory devices may be utilized for memory 106. It is to be noted that memory 106 may be located anywhere within device 100 and, in one instance, it may also be part of baseband module 105.

Transmitter 101 and receiver 102 are coupled to an antenna 104 via transmit/receive (T/R) switch module 103. T/R switch module 103 switches the antenna between the transmitter and receiver depending on the mode of operation. It is to be noted that in other embodiments, antenna arrays may be used, such as beam-forming antenna arrays. Still in other embodiments, separate antennas may be used for transmitter 101 and receiver 102, respectively. Furthermore, in other embodiments, multiple antennas or antenna arrays may be utilized with device 100 to provide antenna diversity or multiple input and/or multiple output, such as MIMO, capabilities.

Outbound data for transmission from host unit 110 are coupled to baseband module 105 and converted to baseband signals and then coupled to transmitter 101. Transmitter 101 converts the baseband signals to outbound radio frequency (RF) signals for transmission from device 100 via antenna 104. Transmitter 101 may utilize one of a variety of up-conversion or modulation techniques to convert the outbound baseband signals to outbound RF signal. Generally, the conversion process is dependent on the particular communication standard or protocol being utilized.

In a similar manner, inbound RF signals are received by antenna 104 and coupled to receiver 102. Receiver 102 then converts the inbound RF signals to inbound baseband signals, which are then coupled to baseband module 105. Receiver 102 may utilize one of a variety of down-conversion or demodulation techniques to convert the inbound RF signals to inbound baseband signals. The inbound baseband signals are processed by baseband module 105 and inbound data is output from baseband module 105 to host unit 110.

LO 107 provides local oscillation signals for use by transmitter 101 for up-conversion and by receiver 102 for down-conversion. In some embodiments, separate LOs may be used for transmitter 101 and receiver 102. Although a variety of LO circuitry may be used, in some embodiments, a PLL is utilized to lock the LO to output a frequency stable LO signal based on a selected channel frequency.

It is to be noted that in one embodiment, baseband module 105, LO 107, transmitter 101 and receiver 102 are integrated on the same integrated circuit (IC) chip. Transmitter 101 and receiver 102 are typically referred to as the RF front-end. In other embodiments, one or more of these components may be on separate IC chips. Similarly, other components shown in FIG. 2 may be incorporated on the same IC chip, along with baseband module 105, LO 107, transmitter 101 and receiver 102. In some embodiments, the antenna 104 may also be incorporated on the same IC chip as well. Furthermore, with the advent of system-on-chip (SOC) integration, host devices, application processors and/or user interfaces, such as host unit 110, may be integrated on the same IC chip along with baseband module 105, transmitter 101 and receiver 102.

Additionally, although one transmitter 101 and receiver 102 are shown, it is to be noted that other embodiments may utilize multiple transmitter units and receiver units, as well as multiple LOs. For example, diversity communication and/or multiple input and/or multiple output communications, such as multiple-input-multiple-output (MIMO) communication, may utilize multiple transmitters 101 and/or receivers 102 as part of the RF front-end. As will be described below, a VCO incorporating one embodiment of the invention is utilized within one or more components of FIG. 2. In one embodiment, the VCO is a component of a PLL used in LO 107.

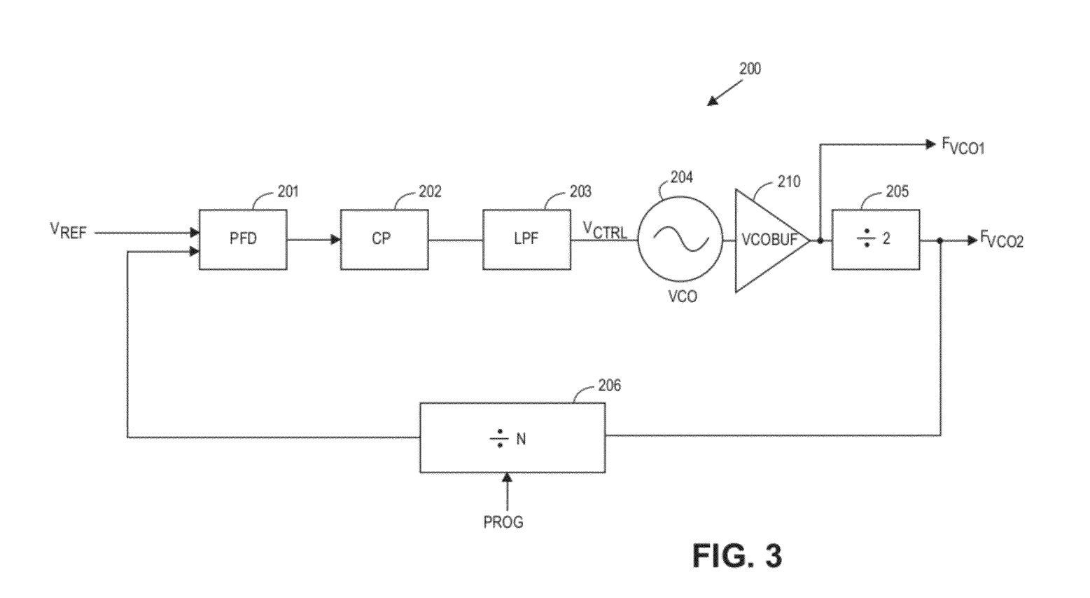

FIG. 3 shows a PLL-based frequency synthesizer 200 that may be implemented as one embodiment for practicing the invention. Synthesizer (or PLL) 200 is a closed loop system utilizing a phase-frequency detector (PFD) 201, charge pump (CP) 202, low-pass filter (LPF) 203, VCO 204 and a divide by N (÷N) circuit 206 in the feedback loop. In this particular embodiment, a VCO buffer (VCOBUF) is used at the output of VCO 204. Some embodiments may not use buffer 210. Also, in this particular embodiment, a divide by 2 (÷2) circuit 205 is used at the output of VCOBUF 210. Other embodiments may utilize a different divider circuit or not use divide by 2 circuit 205.

Divider circuit 206 in the feedback loop may be an integer divider, fractional divider or a combination of both. Divider 206 may be programmable (as shown by program signal PROG in FIG. 3) to programmably select the divisor factor N for synthesizer 200. A control voltage V_{CTRL} at the input of VCO 204 determines the frequency of the signal output from VCO 204. The synthesizer output signal, F_{VCO}, may be obtained at the output of VCOBUF 210 (shown as output F_{VCO1}) or at the output of divide by 2 circuit 205 (shown as F_{VCO2}).

In operation, synthesizer 200 operates as a PLL, in which PFD 201 receives the feedback signal of the synthesizer output from divider circuit 206 and compares the feedback signal to a reference signal V_{REF}. PFD 201 detects any frequency/phase difference and generates an error signal to CP 202 to produce a control voltage. After filtering by LPF 203, the control voltage V_{CTRL} is sent to VCO 204, wherein V_{CTRL} determines the frequency of the signal output from VCO 204. When operating properly, V_{CTRL} is continually adjusted to maintain F_{VCO} output from VCO 204 locked to a particular frequency selected by V_{REF}. As noted above, synthesizer 200 may be incorporated within one of the components noted in FIG. 2 and in one embodiment, synthesizer 200 is used for a PLL-based oscillation signal generator for LO 107. For mobile phone applications, a particular V_{REF}, and hence a particular V_{CTRL} is selected for a given channel frequency to be used for wireless communication.

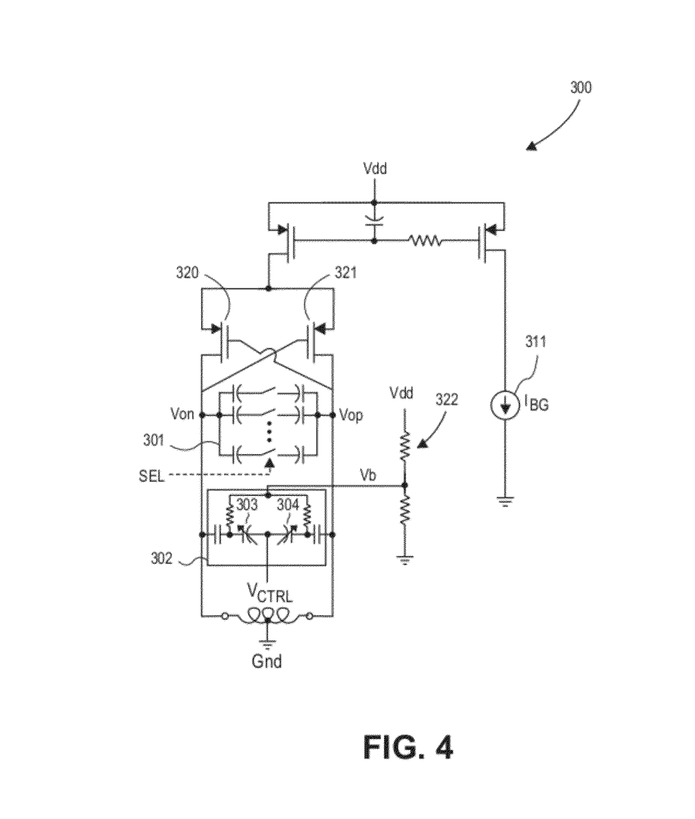

It is to be noted that in many applications, the VCO output frequency F_{VCO} changes based on the operating channel or carrier frequency selected. Likewise a VCO may utilize a variety of different circuitry and techniques to provide the F_{VCO} output as a function of the input V_{CTRL}. FIG. 4 shows one embodiment for implementing a circuit for a VCO, such as VCO 204 of FIG. 3.

FIG. 4 illustrates a VCO circuit 300 comprised of a switched capacitor network (or bank) stage 301, a tuning varactor stage 302 and a pair of cross-coupled differential transistors 320, 321. As noted, in one embodiment, VCO circuit 300 is utilized as VCO 204 of FIG. 3. In one embodiment, switched capacitor network stage 301 is comprised of a plurality of capacitors that are switched in and out by a control signal, noted as SEL. In one embodiment a particular set of capacitor or capacitors of stage 301 is/are selected for coarse frequency setting, such as when a particular communication channel is to be selected. F_{VCO} is shown as a differential output from capacitor network 301. It is to be noted that other reactive components may be utilized in place of a plurality of switched capacitors of capacitor network 301 to provide the frequency selection.

A tuning varactor 302 is coupled to capacitor network 301 and provides the fine tuning adjustment to generate F_{VCO}. V_{CTRL} input is coupled to tuning varactor 302, in which tuning varactor 302 is adjusted by the value of V_{CTRL}. Thus, output F_{VCO} is determined by the selection of capacitors of capacitor network 301 and the tuning adjustment provided by tuning varactor 302 in response to the V_{CTRL} input.

As shown in circuit 300, the plurality of capacitors that comprise switched capacitor network stage 301 are coupled across the drains of cross-coupled differential transistors 320, 321. Tuning varactor stage 302 is also coupled across the drains of the cross-coupled transistors 320, 321. Because of the differential setup, tuning varactor stage 302 is comprised of a pair of varactors 303, 304. A voltage divider network 322 provides the biasing voltage Vb to bias varactors 303, 304. The V_{CTRL} voltage to the VCO is coupled as input to varactors 303, 304 at the junction of the two varactors to provide the fine tuning control for the VCO.

In circuit 300 a bandgap current, I_{BG}, provides the current which is mirrored by the tuning stages to the left of the diagram. Current source 311 is shown generating I_{BG}. It is also to be noted that although P-type transistors are shown in circuit 350, an equivalent circuit may be implemented using N-type devices.

A VCO is expected to maintain a substantially constant frequency output for a given V_{CTRL} input. Typically, this is not a problem when the surrounding environment is static. However, in situations where the operating temperature changes, a VCO may have difficulty maintaining a desired frequency output. Where the VCO is intended to operate over a wide temperature range, an appreciable change in temperature may cause the VCO to drift in frequency. If the frequency drift is significant, the PLL may unlock. Also, this frequency drift is more noticeable at lower supply voltages.

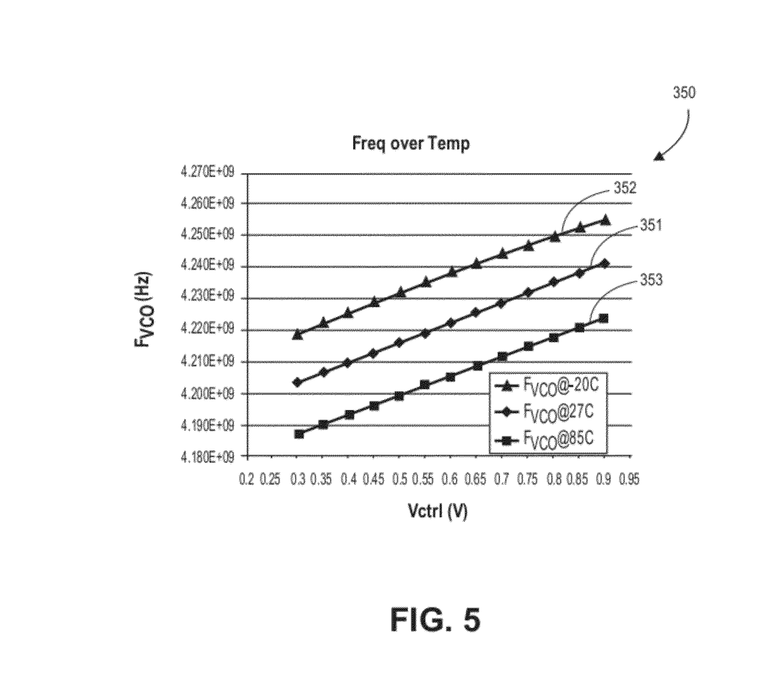

In FIG. 5, a graph 350 illustrates three curves 251-253, in which V_{CTRL} voltage input to the VCO is plotted against the frequency of the VCO output, F_{VCO}. The center curve 351 shows F_{VCO} versus V_{CTRL} at near room temperature (+27° C.), while curve 353 represents the response at approximately +85° C. and curve 352 represents the response at approximately −20° C. Graph 350 assumes an operating range of V_{CTRL} approximately between 0.3V and 0.9V. Note that the lower F_{VCO} frequency value of the nominal curve 351 (at about 4.200 GHz) may not be obtainable when the temperature drops appreciably. At −20 C.°, curve 352 shows the lowest F_{VCO} output at about 4.220 GHz. Likewise, the higher F_{VCO} value of the nominal curve 351 (at about 4.24 GHz) is not obtainable when the temperature rises appreciably. At 85 C.°, curve 353 shows the highest F_{VCO} output at about 4.225 GHz. Assuming that the nominal curve 351 represents the approximate operating range for the VCO output, at the extremities the frequency drift over temperature may be substantial to place the VCO (and hence the PLL) to unlock.

For example, if the PLL is locked to an operating point near the lower end of its frequency range at a given temperature, a drop in temperature may cause an upward shift in the response curve, which could cause the PLL to unlock since that locked frequency is not sustainable at the lower temperature. Likewise, if the temperature rises, it may cause a downward shift in the response curve. Accordingly, such result may cause the wireless device to lose the lock on the selected channel and lose the communication link. As will be described below, a temperature compensating technique is utilized during open-loop calibration to compensate for temperature variations during operation.

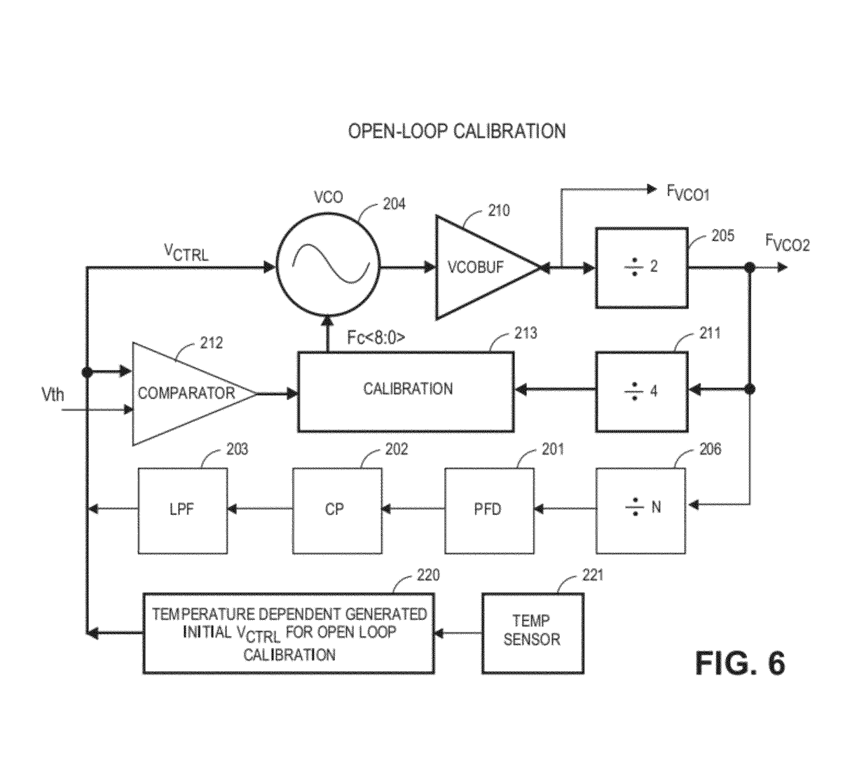

FIG. 6 illustrates an open loop calibration technique for a PLL and described in reference to the PLL depicted in FIG. 3. However, the open-loop calibration technique may be utilized in other configurations as well. The open loop-calibration described herein is a first of two parts of a calibration procedure for practicing an embodiment of the invention. FIG. 6 duplicates synthesizer 200 of FIG. 3 with the addition of a calibration branch and a temperature compensation branch. The calibration branch is comprised of comparator 212, calibration module 213 and divider 211. V_{CTRL} is coupled as one input to comparator 212 and the input to ÷N divider 206 is also coupled as input to ÷4 divider 211. The temperature compensation branch is comprised of a temperature compensation module 220 (noted as “temperature dependent generated initial V_{CTRL} for open loop calibration”) and a temperature sensor 221.

Whenever a VCO or PLL calibration is to be performed, open-loop calibration is performed first followed by closed-loop calibration. The calibration procedure may be performed at various times. For example, the calibration procedure may be performed whenever the channel frequency is set in initiating receive and/or transmit operation(s). The calibration procedure may be performed at other times as well and is not limited to the examples given herein.

The open-loop calibration is performed in order to provide for temperature adjustment (compensation) of VCO 204, in order to have a fairly uniform VCO response to V_{CTRL} over temperature. During open-loop calibration, the components that are utilized are shown as darkened boxes in FIG. 6. That is VCO 204, VCOBUF 210, divider 205, divider 211, calibration module 213, temperature compensation module 220 and temperature sensor 221 are used during open-loop calibration. The feedback loop of the synthesizer (components 206, 201, 202 and 203) are out of the loop and not used during open-loop calibration.

During open calibration, V_{CTRL} is set to a desired fixed value based on temperature. A temperature indication of the surrounding environment (which may be chip temperature, ambient temperature, etc.) is obtained by temperature sensor 221 and an indication of the sensed temperature is sent to temperature compensation module 220. Based on the sensed temperature indication, temperature compensation module 220 adjusts V_{CTRL} which is used during open loop calibration.

In one embodiment, temperature compensation module 220 sets the value of V_{CTRL} to correspond to generating the selected F_{VCO} at the measured temperature. For example, from the F_{VCO} vs. V_{CTRL} relationships of FIG. 5, if the selected F_{VCO} is 4.22 GHz, then depending on the temperature, a corresponding V_{CTRL} is selected.

In another embodiment, temperature compensation is provided by having VCO 204 follow the nominal characteristics over the range of temperatures. For example, from the F_{VCO} vs. V_{CTRL} relationships of FIG. 5, if the selected F_{VCO} is 4.22 GHz, the nominal curve 351 shows a V_{CTRL} of approximately 600 mV. If the temperature is at other than 27° C., then adjustments are made to shift the temperature curve to respond to nominal characteristics for the circuit. For example, if the measured temperature is about 85° C., then adjustments are made to shift curve 353 of FIG. 5 upward to approximate the characteristics shown by nominal curve 351. Likewise, when operating at about −20° C., curve 352 may be shifted downward to approximate the characteristics shown by nominal curve 351.

It is to be appreciated that the manner of how the temperature compensation is provided is not critical to the practice of the invention, as long as some manner of V_{CTRL} adjustment is made based on the temperature indication provided to temperature compensation module 220. This temperature compensation is utilized to compensate for frequency drift of VCO 204 over temperature.

It is also during this open-loop calibration, when the main tuning of VCO 204 is performed for the selected frequency. With the selected V_{CTRL} input to VCO 204, the tuning circuitry of VCO 204 is tuned to generate a designated F_{VCO}, which is fed back to calibration module 213, via divider 211. It is noted that a ÷4 divider is used with this embodiment to further reduce the VCO output being fed back to calibration module 213, but other embodiments may use a different divider or no divider at all.

With regard to circuit 300 of FIG. 4, during open loop calibration, capacitors of capacitor network stage 301 are selected to tune the VCO to generate the selected F_{VCO} output. A variety of programming techniques may be utilized to select which capacitor or capacitors are to be switched in as part of the drain circuit to tune the VCO. As noted previously, a programming signal SEL is used to switch in the correct capacitor(s). In one embodiment, a search is conducted to find the capacitor set up that provides the F_{VCO} that is closest to the desired F_{VCO}. In one embodiment, the search performed is a binary search to find the best capacitor set up.

It is also to be noted that the temperature compensation to adjust for frequency drift (or shift) over temperature may be provided as a continuous adjustment or it may be done in discrete steps. For discrete step changes, temperature compensation module 220 may categorize the overall operating temperature range into temperature regions and adjustments made based on the particular region the temperature measurement falls into. Other embodiments may use other techniques to provide for the temperature adjustment over the operating temperature to compensate V_{CTRL} over temperature.

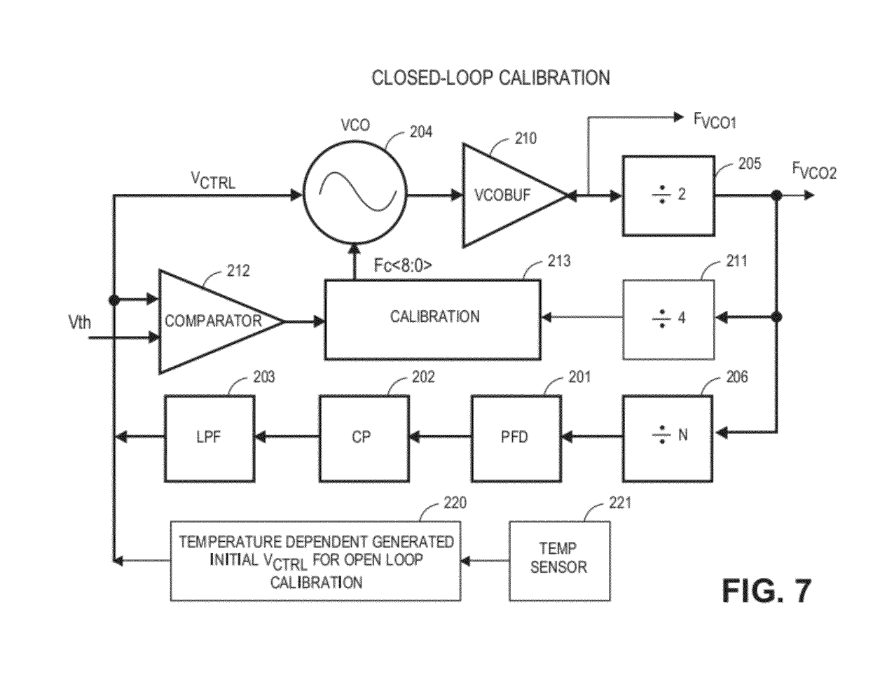

Once the open loop calibration is performed, a closed-loop calibration is performed as the second step of the calibration procedure. FIG. 7 illustrates a closed-loop calibration technique in reference to circuit 300. During closed-loop calibration, the components that are utilized are shown as darkened boxes in FIG. 7. That is VCO 204, VCOBUF 210, divider 205, divider 206, PFD 201, CP 202, LPF 203, as well as comparator 212 and calibration module 213 are utilized. The temperature compensation module 220 and sensor 221 are not utilized. Thus, the feedback loop of the synthesizer (components 206, 201, 202 and 203), which are utilized during normal operation of the PLL are now active. Although the open-loop calibration set the initial F_{VCO} for the VCO that was temperature compensated, the closed loop operation may vary slightly once the feedback loop is inserted in the PLL. Generally, this error is typically related to a single bit error in the setting of the capacitors by the programming signal SEL. That is, when closed-looped, the actual F_{VCO} may be off of the desired F_{VCO} by one capacitor setting in either direction. Accordingly, the closed-loop calibration procedure attempts to correct the least significant bit (1 LSB) error that may manifest in the tuning of VCO 204, when programming bits are used to tune VCO 204.

Although different techniques are available to correct for a LSB error, in one embodiment, a threshold level check is made using comparator 212. A threshold voltage Vth is coupled as an input to comparator 212 and the closed loop V_{CTRL} is coupled as another input to comparator 212. Vth determines the upper and lower limit levels for V_{CTRL} at a given selected F_{VCO}. If V_{CTRL} is within the upper and lower limit (threshold) levels, then no action is needed. However, if V_{CTRL} exceeds either level, then there is an error and the capacitor network is adjusted one position setting in the respective direction, which places the actual F_{VCO} closer to the selected F_{VCO}. Generally, Vth is chosen to correspond to an error of 1 LSB in the tuning selection of the capacitors of the capacitor network 301. However, other embodiments may set the Vth value for adjustments for more than 1 LSB.

Furthermore, only one comparator 212 is shown, but in actual practice two comparators may be used, one for comparing V_{CTRL} to Vth_{LOW} for correcting the frequency in one direction and a second for comparing V_{CTRL} to Vth_{HIGH} for correcting the frequency in the opposite direction. The output of comparator 212 is provided to calibration module 213. If comparator 212 detects VCTRL exceeding the threshold level, then calibration module 213 makes a LSB correction to VCO 204. Note that in the shown example, VCO tuning to set F_{VCO} is controlled by programming bits <8:0>. Although nine bits are used, the actual number of bits for setting the tuning of VCO 204 is a design choice and other embodiments may use more or less than nine bits.

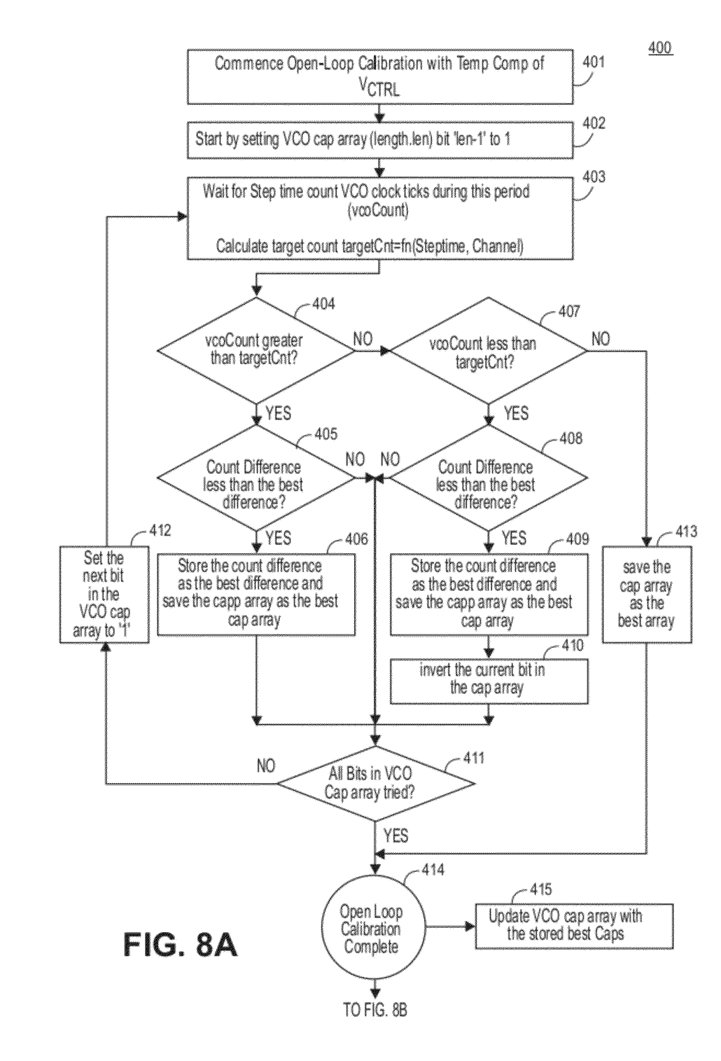

FIGS. 8A-8B illustrate the open-loop, closed-loop calibration procedure performed by calibration module 213 in flow diagram 400. Open-loop calibration commences with the temperature compensation in the selected V_{CTRL} (block 401). Then, the program sequence for the capacitor network (noted as VCO cap array) is initialized (block 402). Depending on the search that is to be performed for the correct capacitor setting, a target count for performing the search is set (block 403). Typically, the number of searches conducted is determined by the number of programming bits utilized for tuning the capacitor network. In one embodiment, a binary search is employed. In other embodiments, other types of searches may be made. In some embodiments, search time parameters may be established as a constant for all bits, but in other embodiments bits may have different search time capabilities, which may also be set in block 403.

At each setting position, the actual F_{VCO} output is compared to the desired value, as was described in reference to FIG. 6, and the difference between the actual and desired is noted. As long as the target count has not been reached (block 407), the calibration routine looks for the best difference between the actual F_{VCO} and the desired value (block 408). The best difference result when looping through the search, is stored (block 409). In each subsequent comparison, the obtained result is compared with the stored result and the better comparison value is stored or retained as the stored value. The search progresses (blocks 410 and 412), until a target count is reached (block 404), at which the final comparison is made (block 405) and the best comparison stored (block 406). Once all of the bits have been transitioned (block 411), the open-loop calibration is completed (block 414), in which the stored value (block 413) contains the bit values for the closest difference between the actual F_{VCO} and the desired F_{VCO} and, hence, corresponds to the best capacitor settings to set the VCO (block 415).

Next, closed loop calibration is performed (block 420), as was described in reference to FIG. 7, when closed-loop calibration is enabled (block 421). It is to be noted that in some instances, device usage is such that closed-loop calibration is not needed. In those instances, closed-loop calibration is not enabled and only open-loop calibration is used. For closed-loop calibration the feed back loop of the PLL is closed and, after a settling time, V_{CTRL} is observed (block 422). If V_{CTRL} exceeds the designated Vth (block 423), the capacitor network is adjusted in the corresponding direction of the exceeded Vth (block 424). The calibration routine is then complete (block 425).

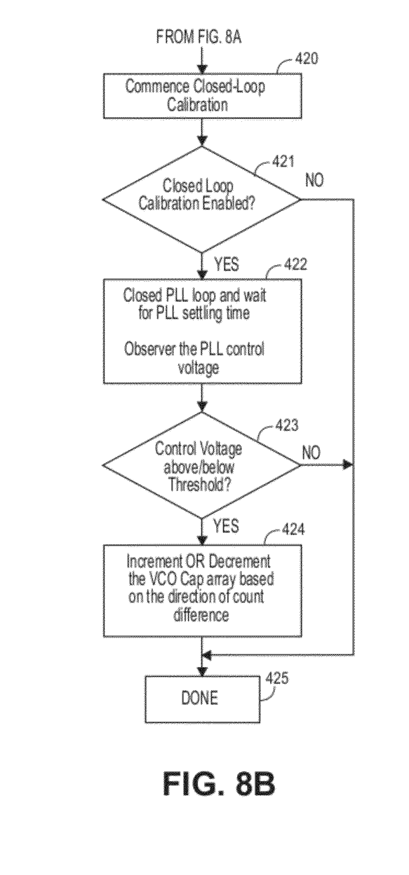

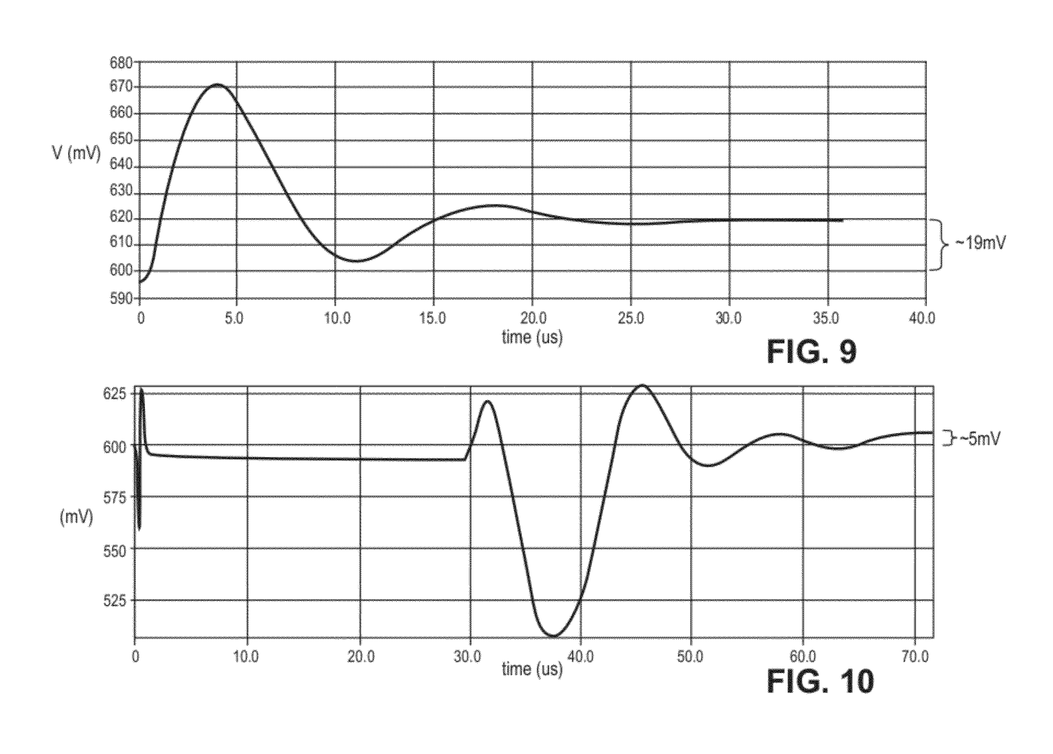

FIGS. 9 and 10 illustrate one example of the difference between performing only the open-loop calibration and both the open-loop and closed-loop calibrations. At a selected F_{VCO} which corresponds to V_{CTRL} of 600 mV after temperature compensation, FIG. 9 shows a result at the end of open-loop calibration. In this instance, there is an approximate +19 mV difference between the actual V_{CTRL} and the desired V_{CTRL} of 600 mV, which translates to a corresponding difference in F_{VCO}. When closed-loop calibration is then performed, assuming that the 19 mV difference exceeded Vth, the 1 LSB correction may be performed reducing the V_{CTRL} error to approximately +5 mV or less. Thus, after closed-loop correction, the actual V_{CTRL} (and therefore F_{VCO}) is much closer to the desired V_{CTRL} (and F_{VCO}).

Accordingly, a VCO calibration scheme that utilizes both open-loop and closed-loop calibration steps is described. The open-loop calibration compensates for temperature in setting the VCTRL and the closed-loop calibration provides for programming bit(s) correction in tuning the VCO. Furthermore, it is to be noted that calibration module 213, as well as temperature compensation module 220, may be implemented in hardware, software, or a combination of both, and including a processor or DSP. Likewise, the calibration procedure of FIGS. 8A-8B may be implemented as an algorithm within calibration module 213.

As may be used herein, the terms “substantially” and “approximately” provides an industry-accepted tolerance for its corresponding term and/or relativity between items. Such an industry-accepted tolerance ranges from less than one percent to fifty percent. Such relativity between items ranges from a difference of a few percent to magnitude differences. As may also be used herein, the term(s) “coupled” and/or “coupling” includes direct coupling between items and/or indirect coupling between items via an intervening item (e.g., an item includes, but is not limited to, a component, an element, a circuit, and/or a module) where, for indirect coupling, the intervening item does not modify the information of a signal but may adjust its current level, voltage level, and/or power level. As may further be used herein, inferred coupling (i.e., where one element is coupled to another element by inference) includes direct and indirect coupling between two items in the same manner as “coupled to”. As may even further be used herein, the term “operable to” indicates that an item includes one or more of power connections, input(s), output(s), etc., to perform one or more corresponding functions and may further include inferred coupling to one or more other items.

The embodiments of the present invention have been described above with the aid of functional building blocks illustrating the performance of certain functions. The boundaries of these functional building blocks have been arbitrarily defined for convenience of description. Alternate boundaries could be defined as long as the certain functions are appropriately performed. One of ordinary skill in the art may also recognize that the functional building blocks, and other illustrative blocks, modules and components herein, may be implemented as illustrated or by discrete components, application specific integrated circuits, processors executing appropriate software and the like or any combination thereof.

We claim:

1. A method comprising:
performing an open-loop calibration on a voltage controlled oscillator (VCO) in an open loop operating mode to tune the VCO by a selected control voltage, in which the selected control voltage is compensated for temperature; and
performing a closed-loop calibration on the VCO in a closed loop operating mode after performing the open-loop calibration, in which the closed-loop calibration corrects for an error in the control voltage that exceeds a predetermined threshold value.

2. The method of claim 1, wherein performing the open-loop calibration includes adjusting tuning component settings in the VCO to search through a plurality of tuning component settings and identify a particular tuning component setting that corresponds closest to the selected control voltage.

3. The method of claim 2, wherein adjusting tuning component settings includes adjusting capacitor settings of a capacitor network to search through a plurality of capacitor settings to identify a particular capacitor setting.

4. The method of claim 2, wherein performing the closed-loop calibration corrects for an error in the control voltage that exceeds the predetermined threshold value when comparing to the selected control voltage.

5. The method of claim 4, wherein performing the closed-loop calibration readjusts the particular tuning component setting when the control voltage exceeds the predetermined threshold value.

6. The method of claim 4, wherein performing the closed-loop calibration readjusts the particular tuning component setting one setting position in a first direction when the control voltage exceeds the predetermined threshold value in a first direction and readjusts the particular tuning component setting one setting position in a second direction when the control voltage exceeds the predetermined threshold value in a opposite direction.

7. A method comprising:
performing an open-loop calibration on a voltage controlled oscillator (VCO) of a phase-locked loop (PLL) when the PLL is in an open loop operating mode, in which a feedback loop of the PLL is not coupled to provide a feedback to the VCO, the open-loop calibration to tune the VCO by a selected control voltage, in which the selected control voltage is compensated for temperature;
coupling the feedback loop of the PLL to the VCO to provide a closed loop PLL; and
performing a closed-loop calibration on the VCO in a closed loop operating mode after performing the open-loop calibration, in which the closed-loop calibration corrects for an error in the control voltage that exceeds a predetermined threshold value.

8. The method of claim 7, wherein performing the open-loop calibration includes adjusting tuning component settings in the VCO to search through a plurality of tuning component settings and identify a particular tuning component setting that corresponds closest to the selected control voltage.

9. The method of claim 8, wherein adjusting tuning component settings includes adjusting capacitor settings of a capacitor network to search through a plurality of capacitor settings to identify a particular capacitor setting.

10. The method of claim 9, wherein performing the closed-loop calibration corrects for an error in the control voltage that exceeds the predetermined threshold value when comparing to the selected control voltage.

11. The method of claim 10, wherein performing the closed-loop calibration readjusts the particular capacitor setting when the control voltage exceeds the predetermined threshold value.

12. The method of claim 10, wherein performing the closed-loop calibration readjusts the particular capacitor setting one setting position in a first direction when the control voltage exceeds the predetermined threshold value in a first direction and readjusts the particular tuning component setting one setting position in an opposite direction when the control voltage exceeds the predetermined threshold value in a opposite direction.

13. An apparatus comprising:
a phase-locked loop (PLL) with a voltage controlled oscillator (VCO) that has a VCO output frequency controlled by a control voltage input to the VCO; and
a calibration module to perform open-loop calibration on the VCO when the PLL is in an open loop operating mode, in which a feedback loop of the PLL is not coupled to provide a feedback to the VCO, the calibration module to perform the open-loop calibration to tune the VCO by a selected control voltage, the calibration module to also perform a closed-loop calibration on the VCO when the feedback loop of the PLL is coupled to the VCO to provide a closed loop PLL, the closed-loop calibration on the VCO performed in a closed loop operating mode after performing the open-loop calibration, in which the closed-loop calibration corrects for an error in the control voltage that exceeds a predetermined threshold value.

14. The apparatus of claim 13, further comprising a temperature compensation module coupled to receive a sensed temperature indication and coupled to the PLL to compensate the selected control voltage input to the VCO for variations in temperature.

15. The apparatus of claim 14, wherein the calibration module when performing the open-loop calibration adjusts tuning component settings in the VCO to search through a plurality of tuning component settings and identify a particular tuning component setting that corresponds to the selected control voltage.

16. The apparatus of claim 15, wherein the calibration module when adjusting tuning component settings adjusts capacitor settings of a capacitor network to search through a plurality of capacitor settings to identify a particular capacitor setting.

17. The apparatus of claim 16, wherein the calibration module when performing the closed-loop calibration corrects for an error in the control voltage that exceeds the predetermined threshold value when comparing to the selected control voltage.

18. The apparatus of claim 17, wherein the calibration module when performing the closed-loop calibration readjusts the particular capacitor setting when the control voltage exceeds the predetermined threshold value.

19. The apparatus of claim 17, wherein the calibration module when performing the closed-loop calibration readjusts the particular capacitor setting one setting position in a first direction when the control voltage exceeds the predetermined threshold value in a first direction and readjusts the particular tuning component setting one setting position in an opposite direction when the control voltage exceeds the predetermined threshold value in a opposite direction.

20. The apparatus of claim 19, wherein the calibration module when performing the closed-loop calibration corrects for one least significant bit (LSB) error in a programming code which adjusts the capacitor settings.
